(19) United States
(12) Patent Application Publication
(10) Pub. No.: US 2018/0246420 A1
(43) Pub. Date: Aug. 30, 2018

(54) A METHOD AND APPARATUS FOR DETERMINING AT LEAST ONE PROPERTY OF PATTERNING DEVICE MARKER FEATURES

(71) Applicant: ASML NETHERLANDS B.V., Veldhoven (NL)

(72) Inventors: Nitesh PANDEY, Eindhoven (NL); Roland Johannes Wilhelmus STAS, 's-Hertogenbosch (NL); Hoite Pieter Theodoor TOLSMA, Eindhoven (NL)

(73) Assignee: ASML NETHERLANDS B.V., Veldhoven (NL)

(21) Appl. No.: 15/753,695

(22) PCT Filed: Aug. 23, 2016
(86) PCT No.: PCT/EP2016/069843

§ 371 Date: Feb. 20, 2018

(30) Foreign Application Priority Data
Sep. 22, 2015 (EP) 15186232.3

(51) Int. Cl. G03F 7/20

(52) U.S. Cl. CPC G03F 7/70666; G03F 7/70633; G03F 7/70525

(57) ABSTRACT

A method comprises determining at least one property of a first marker feature corresponding to a marker of a lithographic patterning device installed in a lithographic apparatus, wherein the first marker feature comprises a projected image of the marker obtained by projection of radiation through the lithographic patterning device by the lithographic apparatus, the determining of at least one property of the projected image of the marker comprises using an image sensor to sense radiation of the projected image prior to formation of at least one desired lithographic feature on the substrate, and the method further comprises determining at least one property of a second marker feature arising from the same marker, after formation of said at least one desired lithographic feature on the substrate.

### CROSS REFERENCE TO RELATED APPLICATIONS

This application claims priority of EP application 15186232.3 which was filed on 2015 Sep. 22 and which is incorporated herein in its entirety by reference.

### FIELD

The present invention relates to a method and apparatus for determining at least one property of patterning device marker features, for example for measuring location of patterning device marker features.

### BACKGROUND

A lithographic apparatus is a machine that applies a desired pattern onto a target portion of a substrate. Lithographic apparatus can be used, for example, in the manufacture of integrated circuits (ICs). In that circumstance, a patterning device, which is alternatively referred to as a mask or a reticle, may be used to generate a circuit pattern corresponding to an individual layer of the IC, and this pattern can be imaged onto a target portion (e.g. comprising part of, one or several dies) on a substrate (e.g. a silicon wafer) that has a layer of radiation-sensitive material (resist). In general, a single substrate will contain a network of adjacent target portions that are successively exposed. Known lithographic apparatus include so-called steppers, in which each target portion is irradiated by exposing an entire pattern onto the target portion in one go, and so-called scanners, in which each target portion is irradiated by scanning the pattern through the beam in a given direction (the “scanning”-direction) while synchronously scanning the substrate parallel or anti parallel to this direction.

It is desirable to be able to monitor or predict actual performance of the lithographic apparatus, in particular the actual image produced by projection of radiation through the mask, which in turn determines at least in part the pattern that may be formed on the substrate by a given mask. The pattern formed on the substrate can be subject to various factors that can vary during operation of the lithographic apparatus.

Reticle align metrology before exposure of a wafer can be performed using a transmission image sensor (TIS) or similar markers which are located at one or more edges of the reticle. Field distortions can be interpolated from these measurements and corrections are passed to the lens models and reticle stage to correct for these distortions during exposure. However, since such metrology markers on the reticle are outside the field and field distortion is interpolated from these measurements, an interpolation error is made.

Reticle (mask) heating can occur during operation of the lithographic apparatus which can result in distortion of the projected image, which in turn causes distortion of the formed pattern. The reticle distortion is in general non-uniform over the reticle's area and hence this results in a non-uniform distortion of the image. There can also be distortions in the image due to the heating of the lens. Such distortions are dynamic in nature as the lens and the reticle heat up during the use of the lithography machine. There can also be vibration effects, or effects arising from variation of properties or alignments, or operations, of mechanical and optical components in practice.

It is known to perform various metrology processes to determine whether the performance of the lithographic apparatus remains within its required specification. For the next generation of lithography, high resolution features of the order of 10-20 nm are required. This results in very tight alignment and focus control requirements. This means that tighter control over imaging quality and operating parameters of the lithographic apparatus, as well as other parts of the process control loop, may be required.

Various techniques are known for measuring or predicting performance of the lithographic apparatus, and the results of such measurements or predictions can be used to set or vary operating parameters.

A typical reticle comprises patterned areas which correspond to the device structure as well as patterned marks which are used for metrology and for image alignment and focussing control, for example. For instance, as mentioned above it is known to include markers alongside the desired projection pattern of the reticle. The image produced by the markers at the substrate table by projection of electromagnetic radiation through projection optics of the lithographic apparatus can be measured, either directly by a sensor or by measurement of a pattern corresponding to the markers formed on a substrate at the substrate table. The image corresponding to the markers can be used to determine a likely level of distortion of features of the lithographic pattern caused by heating of the reticle. However, the markers are positioned at one side of the reticle or at one or more edges of the main lithographic pattern, outside an active area of the reticle where the mask pattern is located, and heating-induced distortion effects may be different in the active area towards the centre of the reticle where the mask pattern is located.

Furthermore, features of the markers are often of a different scale (for example, several microns across) to the scale of individual features of the mask (for example down to around 100 nm or less across) and any distortion of features of the scale of the markers may not always be an accurate guide to the distortion of features of the scale of the mask features. For some particular lithographic systems operating at a wavelength of 193 nm, product features are laid down on the wafer by projection of reticle features of the order of 320 nm across, to produce product features on the wafer of the order of 80 nm across (following a four times demagnification occurring between the reticle and wafer). There are additional features known as assist features deposited on the wafer that are used in optical proximity correction and that are of the order of 13 nm to 25 nm across on the wafer (obtained by projection and associated four times demagnification of corresponding reticle features of the order of 50 nm to 100 nm across). For lithographic systems configured to operate at EUV wavelengths product features deposited on the wafer may be of the order of 10-100 nm across.

Although an estimate of the heating-induced distortion that may be present at the centre of the reticle for a given distortion of the marker patterns can be obtained, there is a limit to the accuracy of such estimates. If the distortion of the product pattern is interpolated from measurements done from the marks present at the edge of the patterns, an interpolation error is made. Reticle heating effects can lead to overlay offsets (e.g. offsets between sequential layers in the deposited pattern) of 3-4 nm in some cases, even when the effects of reticle heating are estimated using marker techniques, or otherwise estimated using a computer model of the reticle heating.

It is known to include smaller markers within an active area of the reticle, near the mask pattern. Such smaller markers can include grating structures that cause corresponding grating patterns to be formed on the substrate following deposition and resist removal. The deposited grating patterns on the resulting wafers can then be analysed for metrology purposes, for example to determine measures of overlay or focus quality. In the case of overlay measurements, marker features, for example, grating structures, can be deposited during deposition of each layer of the lithographic structure and measurement of the marker features for the different layers are used to determine overlay. In some cases, grating structures of marker features of the different layers are deposited on top of each other and resulting interference patterns can be used to determine a measure of overlay.

Measurements performed on actual processed wafers can determine what pattern was deposited in practice by a particular lithographic apparatus and reticle. However, the pattern deposited will depend on other factors in addition to the image formed by the reticle at the image plane of the apparatus. For example, features of the resist, the interaction between the resist and the applied radiation, and subsequent processing of the wafer may also affect the resulting pattern.

### SUMMARY

According to an aspect of the invention, there is provided a method comprising: determining at least one property of a first marker feature corresponding to a marker of a lithographic patterning device installed in a lithographic apparatus, wherein the first marker feature comprises a projected image of the marker obtained by projection of radiation through the lithographic patterning device by the lithographic apparatus. The determining of at least one property of the projected image of the marker comprises using an image sensor to sense radiation of the projected image prior to formation of at least one desired lithographic feature on the substrate, and the method further comprises determining at least one property of a second marker feature arising from the same marker, after formation of said at least one desired lithographic feature on the substrate.

Thus, for example, the same markers, such as diffraction based overlay (DBO) markers, can be used to generate projected images that are measured using an aerial image sensor before an expose step that forms structures on a wafer, and can also be used to determine overlay or other properties after formation of the structures on the wafer.

The at least one property may comprise position or distortion.

The image sensor may be installed at a substrate table that supports the substrate.

The marker may be located within an area of the lithographic patterning device that includes at least one patterning feature for forming said at least one desired lithographic feature on the substrate by projection of radiation through the lithographic patterning device by the lithographic apparatus.

The area may comprise an active area or field of the patterning device. The marker may be located between at least two patterning features each for forming a respective desired lithographic feature (e.g. other than a marker) on the substrate. Each desired lithographic feature may, for example, comprise, represent or form part of a device or circuit component.

The second marker feature may comprise a feature formed on the substrate by physical modification of the substrate due to projection of an image of the marker onto the substrate. The physical modification may comprise modification of at least one property of the substrate, for example a modification of a structural or chemical property of the substrate.

The determining of the at least one property of the second marker feature may be performed after an expose step and/or after an etching step of a lithographic process that forms said at least one desired lithographic feature on the substrate.

The image sensor may comprise a plurality of gratings, each grating having an associated at least one sensing element.

At least one of the sensor gratings may extend in a first direction and at least one other of the sensor gratings may extend in a second, different direction. The directions may be substantially orthogonal.

At least one of the sensor gratings may have a pitch that is different from a pitch of at least one other of the sensor gratings. The pitches may each be in a range 100 nm to 1,000 nm, for example substantially equal to 400 nm, 600 nm, and/or 800 nm

The determining of at least one property of the first marker feature and/or the second marker feature may comprise scanning relative to one another the image sensor and the or a projected image forming the first marker feature or second marker feature, obtaining sensor signals from the sensor during the scanning and determining the at least one property from the sensor signals.

The sensor signals may comprise sensor signals obtained for different relative positions of the image sensor and the first marker feature and/or second marker feature. There may be continuous acquisition of the sensor signals.

The determining of the at least one property of the second marker feature may be performed using a further, different sensor to the sensor used to determine the at least one property of the first marker feature.

The second marker feature may be formed during deposition of one layer of features on the substrate, at least one further feature may be formed on the substrate during deposition of a further layer of features on the substrate, and the determining of the at least one property of the second marker feature may comprise performing a measurement with respect to the second marker feature and the at least one further feature.

The performing of a measurement with respect to the second marker feature and the at least one further feature may comprise performing a measurement with respect to a combination of the second marker feature and the at least one further feature.

The performing of a measurement with respect to the second marker feature and the at least one further feature may comprise performing a measurement of an interferometric and/or diffraction pattern formed by overlay or other combination of the second marker feature and the at least one further feature.

The marker may comprise at least one grating.

The marker may comprise a plurality of gratings, wherein at least one of the gratings extends in a first direction and at least one other of the gratings extends in a second, different direction.

There may be an offset between the phase of at least one of the gratings of the marker and the phase of at least one other of the gratings of the marker.

The lithographic patterning device may comprise a plurality of the markers, and the method may comprise determining said at least one property for each of the plurality of markers.

The marker may be of a first type, the lithographic patterning device may comprise at least one further marker of a second, different type, and the method may comprise determining at least one property of at least one further marker feature arising from said at least one further marker.

The at least one further marker may be outside said area. The lithographic patterning device may further comprise at least one marker of the first type outside said area.

The method may further comprise determining an offset between a location of the marker feature or at least one of the marker features arising from the at least one marker of the first type and a location of said at least one further marker feature arising from the at least one marker of the second type.

The marker may comprise an intra-field overlay marker and/or a diffraction-based overlay marker.

The method may further comprise varying, in a direction perpendicular to a plane of the patterning device, a distance between the patterning device and the image sensor, obtaining measurements using the image sensor for a plurality of the distances, and determining at least one of a focal position and/or a focus correction based on the measurements. The method may comprise determining an image field distortion based on the determined at least one property of the projected image of the marker and the determined at least one property of a second marker feature.

In a further aspect of the invention that may be provided independently, there is provided a lithographic patterning device comprising an area that includes at least one patterning feature for forming at least one desired lithographic feature on a substrate, at least one marker for forming a marker feature in response by projection of radiation through the lithographic patterning device, and at least one further marker outside said area of the patterning device, wherein the at least one marker is of a first type, and the at least one further marker is of a second, different type.

In another aspect of the invention that may be provided independently, there is provided an image sensor for measuring location of a marker feature arising from projection of radiation via a lithographic patterning device that includes at least one marker for producing the marker feature, wherein the image sensor comprises a plurality of gratings and a plurality of sensing elements for sensing radiation that passes through the gratings, wherein at least one of the gratings extends in a first direction and at least one other of the gratings extends in a second, different direction, and at least one of the gratings has a pitch that is different from a pitch of at least one other of the gratings.

In another aspect of the invention that may be provided independently, there is provided a lithographic apparatus comprising: an illumination system for providing a beam of radiation, a support structure for supporting a patterning device, the patterning device serving to impart the radiation beam with a pattern in its cross-section, a substrate table for holding a substrate, a projection system for projecting the patterned radiation beam to provide an image at the substrate table, a sensor installed on the substrate table for sensing at least a region of the image, and a processing resource configured to determine at least one property of a first marker feature corresponding to a marker of the patterning device, wherein the first marker feature comprises a projected image of the marker obtained by projection of the radiation beam through the patterning device, and the determining of at least one property of the projected image of the marker comprises using the sensor to sense radiation of the projected image prior to formation of at least one desired lithographic feature on the substrate, and determine at least one property of a second marker feature arising from the same marker, after formation of said at least one desired lithographic feature on the substrate.

Features in one aspect may be provided as features in any other aspect as appropriate. For example, features of any one of a sensor, apparatus or method may be provided as features of any one other of a sensor, apparatus or method. Any feature or features in one aspect may be provided in combination with any suitable feature or features in any other aspect.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 is a in perspective view of a lithographic apparatus in accordance with an embodiment, schematically showing projection system, patterning device and wafer components of an embodiment shown in FIG. 2;

FIG. 3 is an illustration of a patterning device according to an embodiment;

FIGS. 4A to 4C are schematic illustrations of markers according to an embodiment;

FIGS. 5A and 5B are schematic illustrations of a sensor according to an embodiment;

FIG. 6 is a flowchart of a process performed by an embodiment;

FIG. 7 is a flowchart representing part of the process of FIG. 6;

FIGS. 8A and 8B are schematic illustrations of a scanning process forming part of the process of FIGS. 6 and 7;

FIGS. 9A to 9C are further schematic illustrations of a scanning process forming part of the process of FIGS. 6 and 7;

FIGS. 10A and 10B are illustrations of overlapping grating images formed during a focus-determination process according to an embodiment; and

FIG. 11 is a simulated aerial image plotted as a function of x direction and z-direction (vertical position) of overlapping grating images formed during a focus-determination process according to an embodiment.

### DETAILED DESCRIPTION

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

The term “patterning device” used herein should be broadly interpreted as referring to a device that can be used to impart a radiation beam with a pattern in its cross-section such as to create a pattern in a target portion of the substrate. It should be noted that the pattern imparted to the radiation beam may not exactly correspond to the desired pattern in the target portion of the substrate. Generally, the pattern imparted to the radiation beam will correspond to a particular functional layer in a device being created in the target portion, such as an integrated circuit.

A patterning device may be transmissive or reflective. Examples of patterning device include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions; in this manner, the reflected beam is patterned.

The support structure holds the patterning device. It holds the patterning device in a way depending on the orientation of the patterning device, the design of the lithographic apparatus, and other conditions, such as for example whether or not the patterning device is held in a vacuum environment. The support can use mechanical clamping, vacuum, or other clamping techniques, for example electrostatic clamping under vacuum conditions. The support structure may be a frame or a table, for example, which may be fixed or movable as required and which may ensure that the patterning device is at a desired position, for example with respect to the projection system. Any use of the terms “reticle” or “mask” herein may be considered synonymous with the more general term “patterning device”.

The term “projection system” used herein should be broadly interpreted as encompassing various types of projection system, including refractive optical systems, reflective optical systems, and catadioptric optical systems, as appropriate for example for the exposure radiation being used, or for other factors such as the use of an immersion fluid or the use of a vacuum. Any use of the term “projection lens” herein may be considered as synonymous with the more general term “projection system”.

The illumination system may also encompass various types of optical components, including refractive, reflective, and catadioptric optical components for directing, shaping, or controlling the beam of radiation, and such components may also be referred to below, collectively or singularly, as a “lens”.

The lithographic apparatus may be of a type having two (dual stage) or more substrate tables (and/or two or more support structures). In such “multiple stage” machines the additional tables may be used in parallel, or preparatory steps may be carried out on one or more tables while one or more other tables are being used for exposure.

The lithographic apparatus may also be of a type wherein the substrate is immersed in a liquid having a relatively high refractive index, e.g. water, so as to fill a space between the final element of the projection system and the substrate. Immersion techniques are well known in the art for increasing the numerical aperture of projection systems.

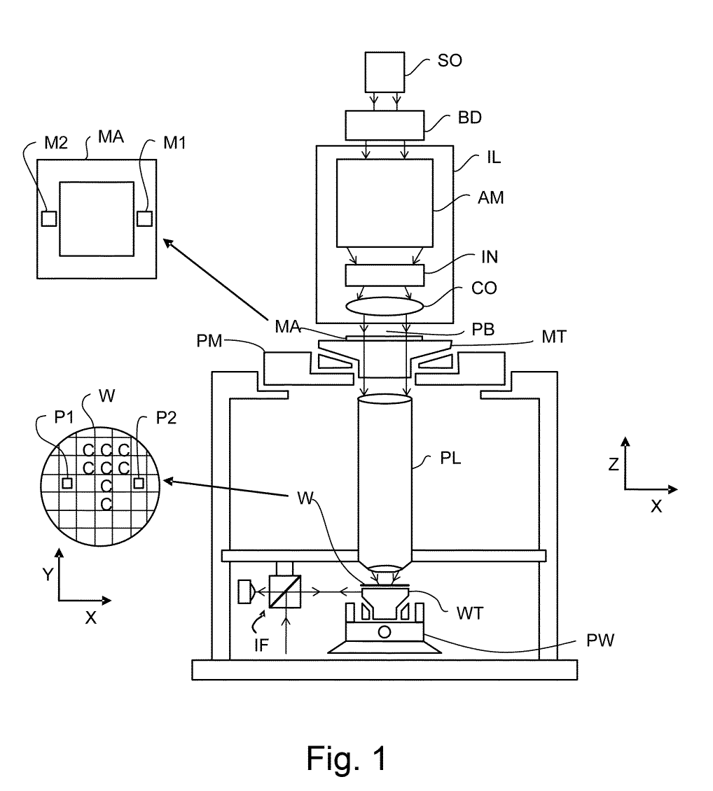

FIG. 1 schematically depicts a lithographic apparatus according to a particular embodiment of the invention. The apparatus comprises:

an illumination system (illuminator) IL to condition a beam PB of radiation (e.g. UV radiation or EUV radiation).

a support structure (e.g. a support structure) MT to support a patterning device (e.g. a mask) MA and connected to first positioning device PM to accurately position the patterning device with respect to item PL;

a substrate table (e.g. a wafer table) WT for holding a substrate (e.g. a resist coated wafer) W and connected to second positioning device PW for accurately positioning the substrate with respect to item PL; and

a projection system (e.g. a refractive projection lens) PL configured to image a pattern imparted to the radiation beam PB by patterning device MA onto a target portion C (e.g. comprising one or more dies) of the substrate W.

As here depicted, the apparatus is of a transmissive type (e.g. employing a transmissive mask). Alternatively, the apparatus may be of a reflective type (e.g. employing a programmable mirror array of a type as referred to above).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases the source may be integral part of the apparatus, for example when the source is a mercury lamp. The source SO and the illuminator IL, together with the beam delivery system BD if required, may be referred to as a radiation system.

The illuminator IL may comprise adjusting means AM for adjusting the angular intensity distribution of the beam. Generally, at least the outer and/or inner radial extent (commonly referred to as -outer and -inner, respectively) of the intensity distribution in a pupil plane of the illuminator can be adjusted. In addition, the illuminator IL generally comprises various other components, such as an integrator IN and a condenser CO. The illuminator provides a conditioned beam of radiation PB, having a desired uniformity and intensity distribution in its cross section.

The radiation beam PB is incident on the patterning device (e.g. mask) MA, which is held on the support structure MT. Having traversed the patterning device MA, the beam PB passes through the lens PL, which focuses the beam onto a target portion C of the substrate W. With the aid of the second positioning device PW and position sensor IF (e.g. an interferometric device), the substrate table WT can be moved accurately, e.g. so as to position different target portions C in the path of the beam PB. Similarly, the first positioning device PM and another position sensor (which is not explicitly depicted in FIG. 1) can be used to accurately position the patterning device MA with respect to the path of the beam PB, e.g. after mechanical retrieval from a mask library, or during a scan. In general, movement of the object tables MT and WT will be realized with the aid of a long-stroke module (coarse positioning) and a short-stroke module (fine positioning), which form part of the positioning device PM and PW. However, in the case of a stepper (as opposed to a scanner) the support structure MT may be connected to a short stroke actuator only, or may be fixed. Patterning device MA and substrate W may be aligned using patterning device alignment marks M1, M2 and substrate alignment marks P1, P2.

The depicted apparatus can be used in the following preferred modes:

1. In step mode, the support structure MT and the substrate table WT are kept essentially stationary, while an entire pattern imparted to the beam PB is projected onto a target portion C in one go (i.e. a single static exposure). The substrate table WT is then shifted in the X and/or Y direction so that a different target portion C can be exposed. In step mode, the maximum size of the exposure field limits the size of the target portion C imaged in a single static exposure.
2. In scan mode, the support structure MT and the substrate table WT are scanned synchronously while a pattern imparted to the beam PB is projected onto a target portion C (i.e. a single dynamic exposure). The velocity and direction of the substrate table WT relative to the support structure MT is determined by the (de-)magnification and image reversal characteristics of the projection system PL. In scan mode, the maximum size of the exposure field limits the width (in the non-scanning direction) of the target portion in a single dynamic exposure, whereas the length of the scanning motion determines the height (in the scanning direction) of the target portion.
3. In another mode, the support structure MT is kept essentially stationary holding a programmable patterning device, and the substrate table WT is moved or scanned while a pattern imparted to the beam PB is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

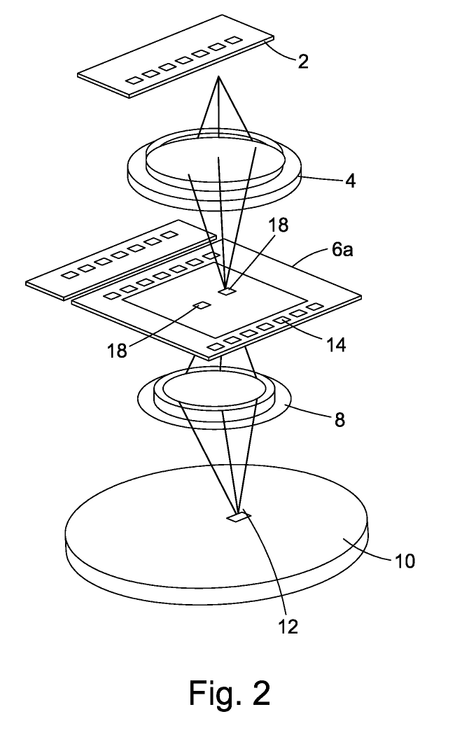

Projection system, patterning device and wafer components of an embodiment shown in perspective view in FIG. 2. In this embodiment, a reticle masking component 2 is located above the projection system represented schematically by lenses 4, 8. The patterning device MA is in the form of a reticle 6a that is located between the lenses 4, 8. The reticle 6a and projection system 4, 8 are arranged to project a mask image onto components located on the wafer table WT.

In the arrangement shown in FIG. 2, the substrate table WT has been moved by positioning device PW such that at least part of the mask image has been projected onto a transmission image sensor (TiS) 12 located at the substrate table WT.

It is a feature of the reticle 6a of the embodiment that marker features 18 are provided in an active area of the reticle 6a. Two marker features 18 are shown in FIG. 2, but any desired number of marker features may be provided. The active area of the reticle 6a also includes patterning features for forming at least one desired lithographic feature on a wafer by projection of radiation through the reticle 6a. The marker may be located between at least two patterning features each for forming a respective desired lithographic feature (e.g. other than a marker) on the substrate. Each desired lithographic feature may, for example, comprise, represent or form part of a device or circuit component.

Further markers 14 of different type to the marker features 18 are also provided on the reticle 6a outside the field, or active area, of the reticle 6a. The further markers 14, may, for example, be located not between any at least two patterning features each for forming a respective desired lithographic feature.

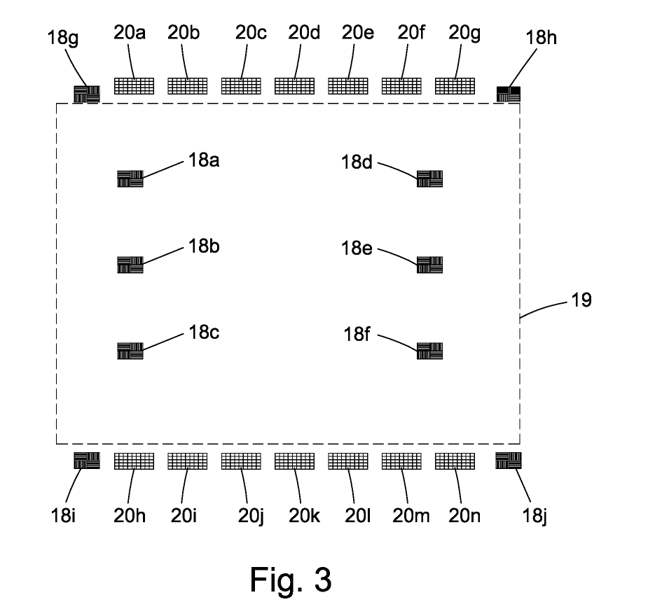

A reticle 6b according to an embodiment is shown in face-on view in FIG. 3. The reticle 6b is used in place of reticle 6a in the embodiment of FIG. 2, and includes six marker features 18a, 18b, 18c, 18d, 18e, 18f in the active area 19 of the reticle 6b. Again, the active area 19 of the reticle 6b also includes patterning features for forming at least one desired lithographic feature on a wafer by projection of radiation through the reticle 6b, but the patterning features are not shown in FIG. 3 for clarity.

The markers 18a, 18b, 18c, 18d, 18e, 18f are micro-diffraction based overlay markers that, in operation, can be used to form marker features on the wafer by physical modification of the wafer due to projection of an image of the marker onto the substrate during an expose step(s) of a lithographic process that also forms the at least one desired lithographic feature on the wafer. The marker features can then be used to determine overlay effects based on measurements of position of the marker features formed on the substrate, subsequent to the expose step(s) and/or an etching step(s) of the lithographic process.

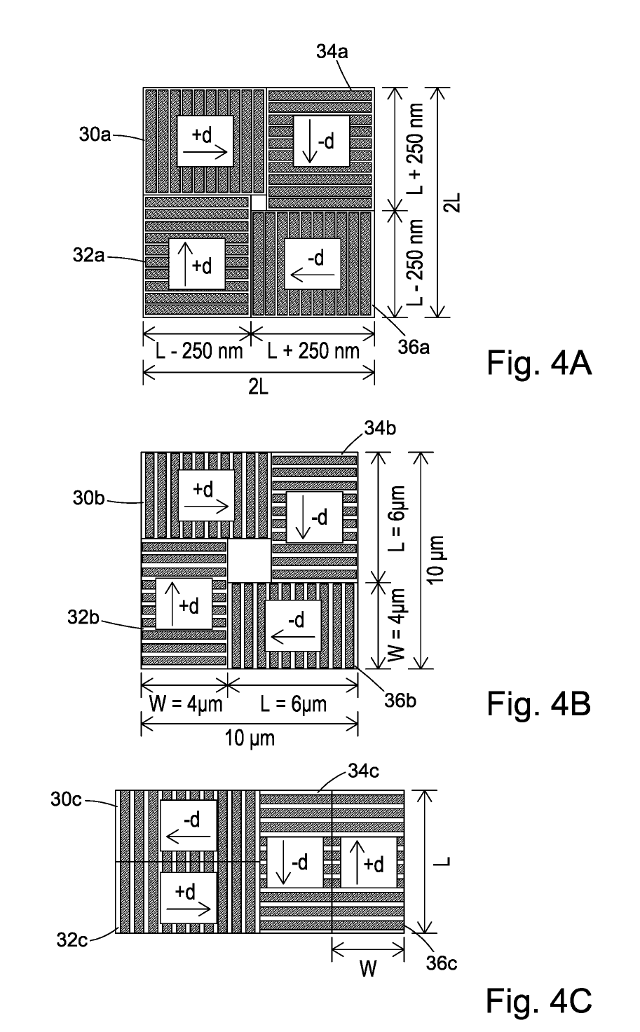

It is a feature of the embodiment of FIGS. 2 and 3 that at least one property (for example, position) of further marker features derived from the markers 18a, 18b, 18c, 18d, 18e, 18f in the form of projected images of the markers 18a, 18b, 18c, 18d, 18e, 18f are also determined using an aerial image sensor in the form of sensor 12 prior to an expose step and/or an etching step of the lithographic process and prior to formation of at least one of the desired lithographic features on the substrate. The structure and function of the markers 18a, 18b, 18c, 18d, 18e, 18f are discussed in more detail below in relation to FIGS. 4 to 7.

The reticle 6b includes further markers 18g, 18h, 18i, 18j of the same, first type as markers 18a, 18b, 18c, 18d, 18e, 18f. The further markers 18g, 18h, 18i, 18j are located outside the active area 19 of the reticle 6b.

The reticle 6b also includes a set of further markers 20a-20n of a second, different type that are also located outside the active area 19 of the reticle 6b. The further markers 20a-20n in this embodiment are larger (for example 400 μm×200 μm) than markers 18a-18j (of size 10 μm×10 μm in some embodiments) and are of known type used for determination of reticle heating effects by aerial image measurements prior to formation of at least some of the desired lithographic features on the wafer.

Each of the further markers 18g, 18h, 18i, 18j of the first type is located adjacent to, and at a known distance from, a respective one 20a, 20g, 20h, 20n of the further markers of the second type.

FIG. 4A shows one of the markers 18 in more detail. The marker 18a comprises four gratings 30a, 32a, 34a, 36a positioned closely together such that in operation they can be simultaneously illuminated, and imaged by sensor 12.

Two of the gratings 30a, 36a extend in the first direction and the other two of the gratings 32a, 34a extend in a second, different direction. In this embodiment the first direction and the second direction are perpendicular to one another. In the embodiment of FIG. 4A, each grating is substantially of size 5 μm×5 μm (±250 nm in or both directions) although the gratings can be of any suitable size in alternative embodiments. The pitch or periodicity of each grating 30a, 32a, 34a, 36a in this embodiment is 500 nm, but any other suitable pitch or periodicity may be used in alternative embodiments. For example, in some embodiments, the pitch or periodicity of each grating is in a range 400 nm to 800 nm. The values of L shown in FIGS. 4A to 4C is, are some embodiments in a range 5,000 nm to 8,000 nm.

Gratings 30a, 32a, 34a, 36A are differently biased, with gratings 30a, 32a having a bias of +d and gratings 34a, 36a having a bias of −d. The bias can also be referred to as a phase difference.

Due to the bias/phase difference between gratings, if the gratings were printed at the same location there would a lateral offset between lines or other grating features (in addition to any orientation differences between the gratings). For example, if an image of grating 30a was printed or otherwise projected at a location, and an image of grating 34a was printed or otherwise projected at the same location there would be lateral offset of 2d (difference between +d and −d) between corresponding lines or other features of the grating (in addition to the difference in orientation). Phrased differently, printing or otherwise projecting the images of grating 30a and grating 34a so that lines of grating 30a were exactly overlaid with lines of grating 34a could be achieved by a rotation of 90 degrees, a lateral shift by the size of the grating and a further lateral shift of 2d (the difference between the biases/phase difference of +d and −d).

FIG. 4B shows one of the markers 18 of the first type according to an alternative embodiment. It can be seen that the sizes and offsets of the gratings 30b, 32b, 34b, 36b are different from those of the gratings of FIG. 4A.

FIG. 4C shows one of the markers 18 of the first type according to a further alternative embodiment. It can be seen that the sizes and offsets of the gratings 30c, 32c, 34c, 36c are different from those of the gratings of FIGS. 4A and 4B.

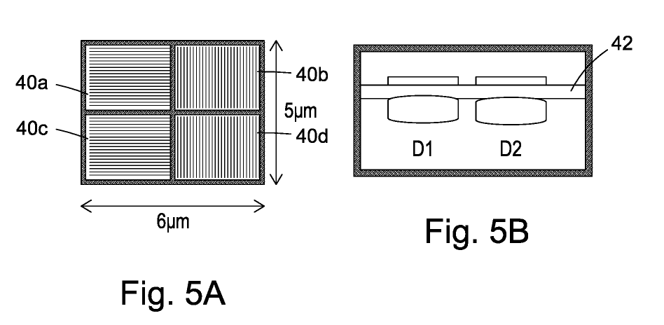

The sensor 12 of the embodiment of FIG. 2 is illustrated in more detail in FIGS. 5A and 5B.

The sensor comprises an array of gratings 40a, 40b, 40c, 40d with a respective detection element in the form of a photo-sensitive diode, or any other suitable form of detection element, positioned beneath each grating 40a, 40b, 40c, 40d. FIG. 5B shows a cross-sectional view of the sensor 12, which is shown in a face-on view in FIG. 5A. Detection elements D1 and D2 can be seen located beneath gratings 40c, 40d.

Each of the detector elements is configured such that it produces a measurement of a magnitude that is dependent on the amount of radiation having a wavelength in an appropriate range that impinges on the detector element. The sensor may include appropriate circuitry for obtaining measurement signals from the detector elements, for example filters, integrators, sample and hold circuitry.

Processing of the measurement signals from each of the detection elements is performed by a processing resource. In some embodiments the processing resource is in the form of on-board circuitry, for example an ASIC or integrated circuit. In other embodiments the processing resource is in the form of an external processing resource, for instance a suitably programmed general purpose computer or a control computer of the lithographic apparatus.

The gratings of the sensor 12 are in the form of chrome lines or other features etched or otherwise provided on a glass substrate 42. Two of the gratings 40a, 40c extend in a first direction and the other two of the gratings 40b, 40d extend in a second, different direction. In this embodiment the first direction and the second direction are perpendicular to one another. In the embodiment of FIGS. 5A and 5B, each grating is substantially of size 2.5 μm×3 μm although the gratings can be of any suitable size in alternative embodiments.

There is a phase difference between the gratings 40a and 40c extending in the horizontal direction in the figure, and there is also a phase difference between the gratings 40b and 40d extending in the vertical direction in the figure.

The pitch or periodicity of each grating 40a, 40b, 40c, 40d in this embodiment is 500 nm, but any other suitable pitch or periodicity may be used in alternative embodiments. For example, in some embodiments, the pitch or periodicity of each grating is in a range of 100 nm to 800 nm.

The sensor 12 of FIGS. 5A and 5B is shown as comprising an array of gratings and associated detection elements. In alternative embodiments, any suitable number of gratings and detection elements may be provided. For example, in a variant of the embodiment of FIGS. 5A and 5B, the sensor 12 comprises three arrays of gratings and associated detection elements, each array being as shown in FIG. 5A, but with the gratings of each array having a pitch or periodicity that is different from the pitch or periodicity of the gratings of each other array.

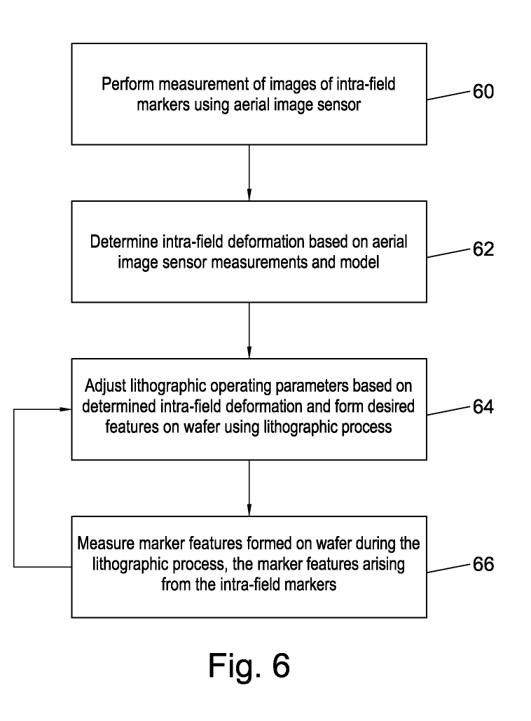

A process for using marker features derived from intra-field markers 18 to determine reticle heating effects, overlay or other distortions is described in overview in relation to the flow chart of FIG. 6.

The process of FIG. 6 is performed using the lithographic apparatus of FIGS. 1 and 2, in which a reticle 6 including intrafield markers 18 is in place, and in which a wafer is installed on the wafer table WT.

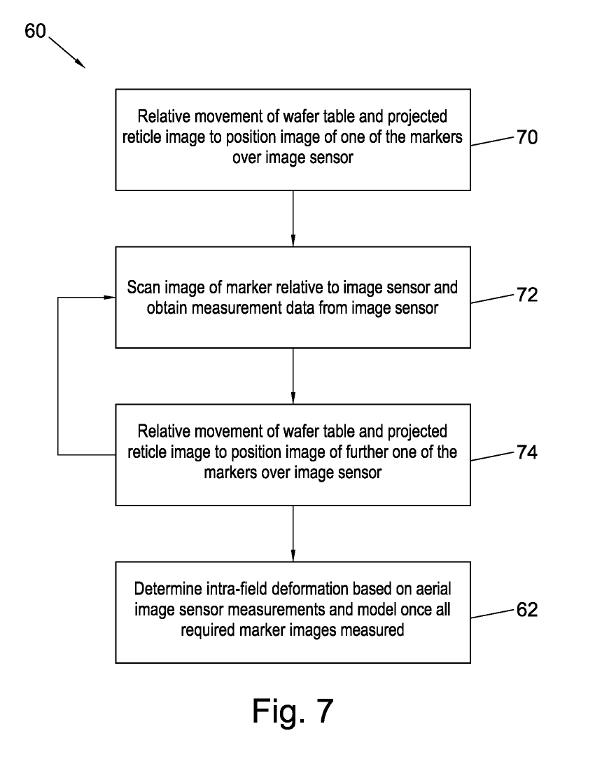

At the first stage 60 of the process of FIG. 6, marker features in the form of images of the intrafield markers 18 of the reticle 6 are detected using aerial image sensor 12 installed at the wafer table WT. Images of markers 6 at various positions within the active area of the reticle 6 are measured using the sensor 12. The measurement process at stage 60 is described in more detail below with reference to FIG. 7. The measurements may be interpolated to provide an indication of image distortion over the whole area of the image field if so desired.

At the next stage 62, the measurements of the marker images are used to determine distortions of the image field produced by reticle heating, projection optics artefacts or other effects. For example, a known thermal model for intra-wafer die-to-die deformation may be used to determine thermal-induced reticle distortion effects across the reticle image field at the wafer table WT based on the marker image measurements. Such thermal and other models, and the use of such models to estimate or otherwise determine image field distortions, are known. However, in the embodiment of FIG. 6 the marker image measurements that are used in the model are from the intra-field markers 18 and thus, in some cases, the model can provide for greater accuracy than models or versions of the model that use only measurements derived from markers positioned outside the image field.

At the next stage 64, lithographic operating parameters of the lithographic apparatus are adjusted based on the determined intra-field deformation. The lithographic process is then performed in the normal way to form desired features on the wafer by projecting radiation through the reticle, with patterning features on the reticle causing formation of the desired features on the wafer. The lithographic process comprises various stages with the formation of various layers one on top of the other, and an associated resist removal process, before formation of the desired structures is completed.

At each deposition stage, marker features corresponding to the projected images of the intra-field markers 18 are also formed on the wafer. In the embodiments of FIGS. 3 and 4, the marker features are in the form of grating structures.

At the next stage 66, measurements of the marker features deposited on the wafer and corresponding to the intra-field markers 18 are performed using known techniques. In the embodiment of FIG. 6, the measurements of the marker features corresponding to the intra-field markers 18 are performed using a further sensor different from the sensor 12 used to measure the projected images of the markers at stage 60.

The further sensor used to perform at stage 66 measurements of the marker features deposited on the wafer and corresponding to the intra-field markers 18 may, in some embodiments, be the same as or similar to the metrology apparatus in the form of a scatterometer described in US 2014/0233031, the content of which is hereby incorporated by reference. The further sensor may, for example, in some embodiments be the same as or similar to the scatterometer described in relation to FIG. 3A of US 2014/0233031. The further sensor may be in the form of a stand-alone apparatus and the wafer may be transferred from the lithographic apparatus to the stand-alone sensor apparatus in order to perform the measurements of the marker features. Alternatively, the further sensor can be installed in the lithographic apparatus, for example at a measurement table (not shown) separate from the wafer table in some variants of the embodiment of FIG. 2.

The measurements of the marker features formed on the wafer and corresponding to the intra-field markers 18 at stage 60 may comprise interferometric measurements that can be used to determine the location of the marker features. The marker features can include marker features corresponding to the intra-field markers 18 and are formed during formation of different layers during the lithographic process. Measurements performed by the further sensor of the marker features formed on the wafer can be used to determine overlay between the different layers in accordance with known techniques.

It is known to form structures on a wafer corresponding to intra-field markers on a reticle, and then to perform measurements to determine overlay effects. The measurement of marker features and stage 66 the process of FIG. 6 can be performed in accordance with any such suitable known techniques.

It is a feature of the embodiment of FIG. 6 that, as well as performing measurements of properties (for example position) of structures derived from intra-field markers and formed on a substrate during a lithographic process in order to determine overlay effects, measurements are also performed at stage 60 on marker features, in this case projected images, derived from the same intra-field markers. Thus, the same intra-field markers can be used to determine image deformations (for example, due to reticle heating or other effects) using an aerial image sensor prior to the lithographic process, and can also be used to determine overlay or other effects following the lithographic process.

The process of measuring, at stage 60, marker features in the form of images of the intrafield markers 18 of the reticle 6 using aerial image sensor 12 installed at the wafer table WT is now described in more detail with reference to FIG. 7.

At the first stage 70 of the measurement process at stage 60, there is a relative movement between the wafer table WT and reticle 6 such that an image of one of the intra-field markers 18 is positioned over the sensor 12.

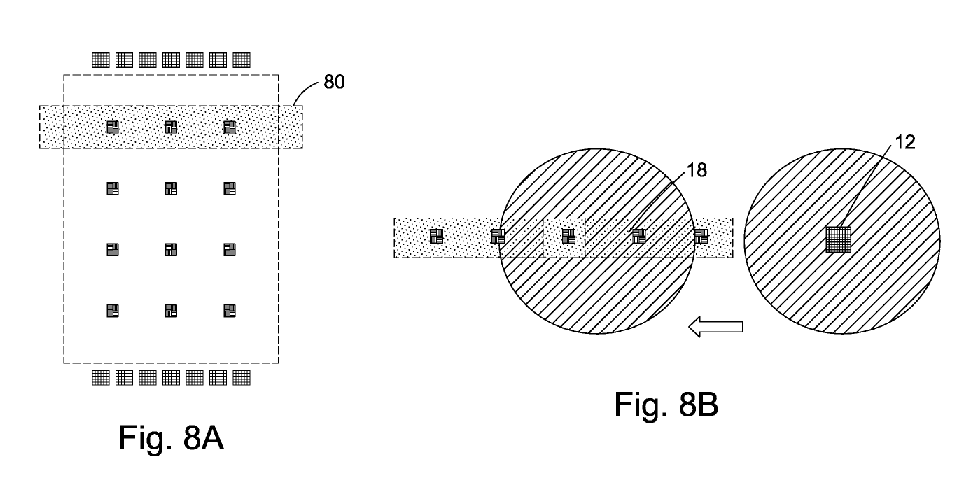

As can be seen from FIG. 8A, only a selected area 80 of the reticle 6 is illuminated at any time, with the area 80 being selected by movement of the reticle support structure MT relative to the radiation beam provided by the projection system. The illumination of the area 80 generates a projected image 82, which is projected to the wafer table WT. The initial relative movement of the wafer table WT and reticle 6 at stage 70 of FIG. 7 to position an image of one of the intra-field markers 18 over the sensor 12 is illustrated schematically in FIG. 8B.

At the next stage 72, the image of the marker 18 is scanned over the image sensor 12, for example by movement of the wafer table WT. Measurements from the detection elements of the sensor 12 are obtained during the scanning of the image of the marker 18 over the image sensor 12. In the embodiment of FIG. 7, the sensor 12 stays within the projected image of the marker 18 during the scanning process.

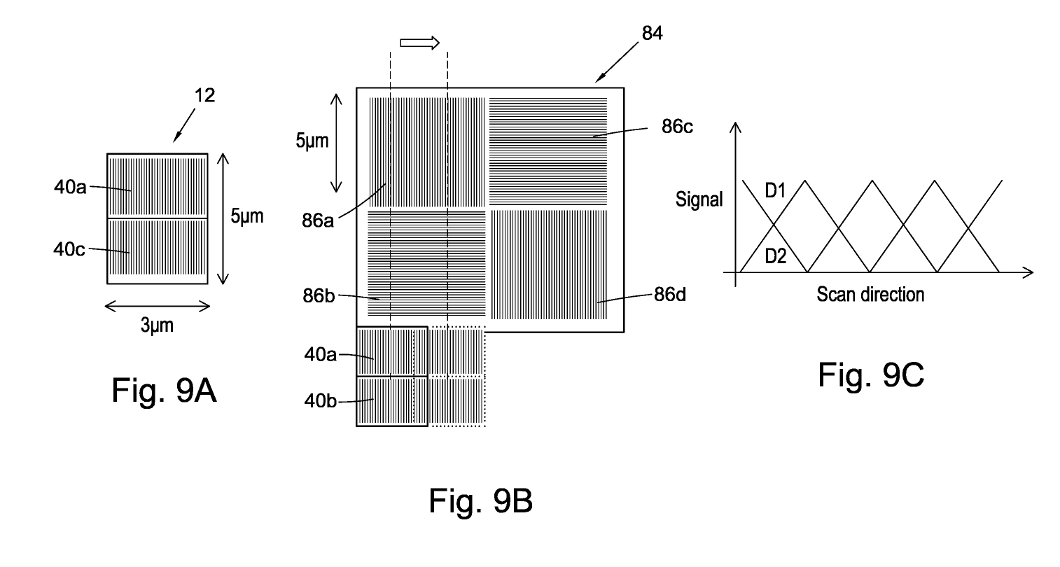

The process of scanning of the image of the marker 18 over the image sensor 12 at stage 72 is illustrated schematically in FIGS. 9A to 9C. Only two of the gratings 40a, 40c of the sensor 12 are shown in FIGS. 9A to 9C, although in other embodiments more than two gratings and associated detector elements may be provided in the sensor 12 as discussed.

FIG. 9A schematically shows the sensor area, in this case 3 μm×5 μm comprising two gratings 40a, 40c with a different phase. As shown in FIG. 9B, the detector 12 is scanned relative to the projected image 84 of the marker 18. The projected image 84 comprises projected images of grating structures 86a, 86b, 86c, 86d that correspond to grating structures of the marker 18. In the case of FIG. 9B, a scanning of the gratings 40a, 40c from a start position to an end position, indicated by dashed lines, is considered by way of illustration. The scan produces a variation of signals from detectors D1 and D2 beneath gratings 40a, 40c as shown in FIG. 9C. The signals of D1 and D2 are out of phase due to the bias/phase difference between the gratings 40a, 40c and also due to the bias/phase difference between gratings of the marker 18. In this case, a parameter S=(D1−D2)/(D1+D2) is calculated to give a normalized measure that can be used to determine the position of the marker feature in the form of the projected image 84.

In many embodiments, more than two grating structures are provided in the sensor 12, and measurements from each of the detector elements corresponding to the grating structures are combined to determine the position of the marker feature.

At the next stage, indicated with 74, there is further relative movement of the wafer table WT and projected image of the reticle, to position a projected image of a further one of the intra-field markers over the sensor 12. The scanning of the image of the marker relative to the image sensor 12 at stage 72 is then repeated for the further intra-field marker and measurements are obtained using the sensor 12, which can be used to determine a position of the projected image of the further marker. Stages 74 and 72 are then repeated for selected ones of the markers 18 of the reticle.

At stage 62, the measurements obtained from the sensor 12 for each of the selected markers are used to determine intra-field deformation as described above in relation to FIG. 6.

It is found that if a pitch of the gratings of the sensor 12 is equal to half of the pitch of the gratings of the marker 18 then no useful measurement signal may be obtained. Therefore, in some embodiments, the sensor 12 includes a plurality of gratings, with at least some of the gratings having pitches that are different from at least some other of the gratings. Thus, measurement signals from appropriate gratings can be selected and used dependent on the pitch of gratings of the particular marker that is being measured. In some embodiments, the gratings of the sensor 12 have pitches of 400 nm, 600 nm and 800 nm.

The processes of FIGS. 6 and 7 are, in some embodiments, repeated for each wafer that is installed in the lithographic apparatus and subject to a lithographic process. The process at stage 60 of FIG. 6, and considered in more detail in relation to FIG. 7, can enable image deformations in the x-y plane (e.g. the plane parallel to the substrate) to be determined and may be performed for each wafer.

In some embodiments a further process is performed to map inherent focus distortions (for example distortions in the z-direction, orthogonal to the plane of the wafer table) as a function of position, or to determine optimum focus position, based on using the image sensor 12 to detect projected images of the markers 18. Such a further process to determine focus distortions may, in some embodiments, be performed once, or a limited number of times, for each reticle rather than for each wafer. The optimum position of the wafer table may be determined, or a focus correction that may need to be applied for a given wafer table position may be determined, from the focus distortion mapping.

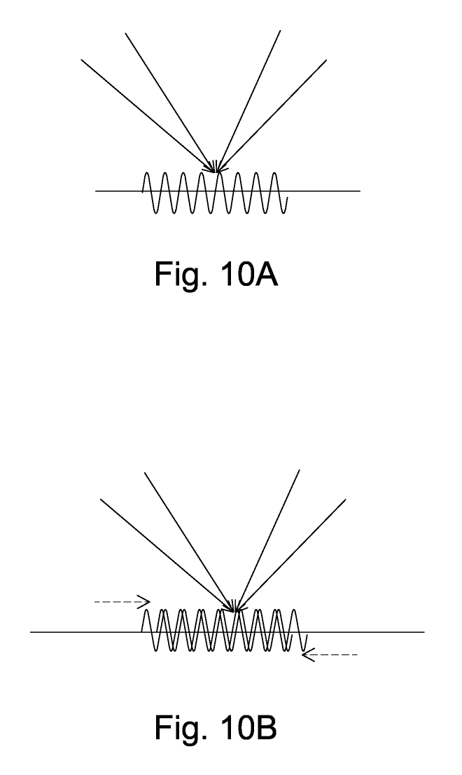

In the further process each grating 18, or a selected number of the gratings, are in turn imaged by applying off-axis dipole radiation. The two resulting incoherent grating images are detected by the image sensor 12. The two detected grating images are perfectly, or optimally overlapped, at the position of best focus (e.g. when the wafer table WT and thus sensor 12 are at the vertical position of best focus), as represented schematically in FIG. 10A where the arrows represent light beams forming the grating image. If the sensor moves away vertically from the focal plane, the two overlapping grating images become unaligned and the resultant image changes, as illustrated schematically in FIG. 10B. The further process comprises scanning the wafer table through a range of vertical positions (z direction) and, if necessary, through a range of horizontal positions and detecting the radiation forming the projected grating images at the sensor 12.

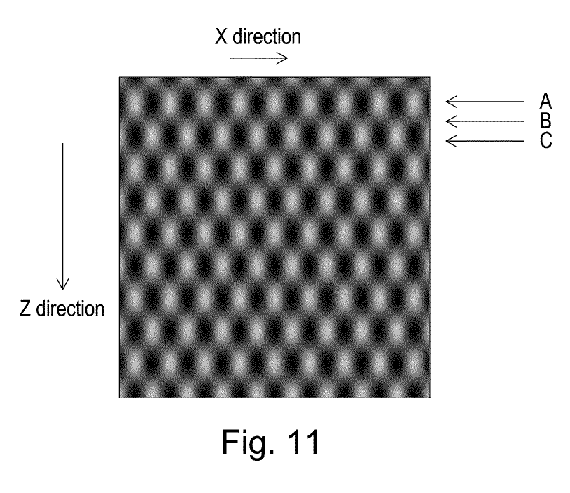

FIG. 11 is a simulated aerial image formed with overlapping gratings and plotted as a function of x direction and z-direction (vertical position) as would be sensed by the sensor 12 during the further process to determine focus distortions or focus position. Arrow A indicates the vertical position of the wafer table WT at which the image of the intra-field marker 18 is focused. Arrow B indicates a position at which the image is out of focus such that there is substantially zero variation of contrast as a function of position in the x direction. Arrow C indicates a position at which there is reversal of contrast in the image.

The measurements by the image sensor 12 during the further process can be used in some embodiments to select the optimum vertical position for the wafer table and/or to determine a focus correction that may need to be applied for a given wafer table position. In some embodiments, the further process comprises stepping the sensor 12 through a series of vertical positions (e.g. positions in the z direction) for example to obtain a periodic signal, and then fitting the signal to a suitable function to obtain the position of best focus and/or to determine a focus correction.

In some embodiments the further process to determine focus is performed only once per reticle in contrast to the processes of FIGS. 6 and 7, which may be performed for each wafer.

As shown for example in FIG. 3, in some embodiments the reticle includes further markers 18g, 18h, 18i, 18j as the same type as the intra-field markers 18a, 18b, 18c, 18d, 18e, 18f but positioned outside the field or active area, and also includes a set of a set of further markers 20a-20n of a second, different type that are also located outside the active area or field 19 of the reticle.

In some embodiments marker features such as projected images that correspond to the intrafield markers, the further markers of the same type, and the further markers of the second, different type are each measured, for example using the sensor 12. In some embodiments, one or more of the markers of the first type are known diffraction based overlay (DBO) markers, and one or more of the markers of the second type are known transmission image sensor (TiS) markers.

Offsets on the reticle between intrafield markers, the further markers of the same type, and the further markers of the second, different type are known. In some embodiments, offsets (for example offset distances at the plane of the wafer table WT) between corresponding marker features obtained from the intrafield markers, the further markers of the same type, and the further markers are obtained. In some embodiments the offsets are obtained between marker features for a variety of different conditions, for example a variety of different heating conditions, and/or for a variety of different image distortions. In some embodiments a correlation or calibration is obtained between image distortions determined based on the position of marker features (for example projected images or features deposited on the wafer) corresponding to the markers 18 of the first type and determined using an aerial image sensor, and image distortions determined based on the position of marker features (for example projected images or features deposited on the wafer) corresponding to the markers of the second, different type 20. Some embodiments can provide for a comparison between expected intra-field image distortions determined based on extrapolation or interpolation of measurements of marker features derived from the markers 20 outside the field, and actual measured intra-field image distortions determined based on measurements of the marker features derived from the intra-field marker.

The sensors, reticles and markers of described embodiments can be used with a lithographic apparatus using any suitable wavelengths of electromagnetic radiation for lithographic purposes, for example wavelengths in a range 4 nm to 400 nm, for instance commonly used wavelengths in a range 100 nm to 400 nm such as 365 nm, 248 nm, 193 nm, 157 nm or 126 nm. The sensors reticles and markers can be used with lithographic apparatus using any suitable wavelengths of electromagnetic radiation in or near the extreme ultraviolet (EUV) range, for example wavelengths in the range 4 nm to 25 nm.

It is a feature of certain embodiments that the same intra-field markers, for example diffraction based overlay (DBO) markers, can be used to generate projected images that are measured using an aerial image sensor before an expose step that forms structures on a wafer, and can also be used to determine overlay or other properties after formation of the structures on the wafer.

While specific embodiments of the invention have been described above, it will be appreciated that the invention may be practiced otherwise than as described. The description is not intended to limit the invention.

1. A method comprising:
determining an image field distortion of a first marker feature corresponding to a marker of a lithographic patterning device installed in a lithographic apparatus, wherein:
the first marker feature comprises a projected image of the marker obtained by projection of radiation via the lithographic patterning device by the lithographic apparatus,
the determining of the image field distortion of the projected image of the marker comprises using an image sensor to sense radiation of the projected image prior to formation of at least one desired lithographic feature on the substrate; and
determining at least one property, different from image field distortion, of a second marker feature arising from the same marker, after formation of the at least one desired lithographic feature on the substrate.

2. The method according to claim 1, wherein the marker is located within an area of the lithographic patterning device that includes at least one patterning feature for forming the at least one desired lithographic feature on the substrate by projection of radiation via the lithographic patterning device by the lithographic apparatus.

3. The method according to claim 1, wherein the second marker feature comprises a feature formed on the substrate by physical modification of the substrate due to projection of an image of the marker onto the substrate.

4. The method according to claim 1, wherein the determining of the at least one property of the second marker feature is performed after an expose step and/or after an etching step of a lithographic process that forms the at least one desired lithographic feature on the substrate.

5. The method according to claim 1, wherein the image sensor comprises a plurality of gratings, each grating having an associated at least one sensing element.

6. The method according to claim 5, wherein at least one of the sensor gratings extends in a first direction and at least one other of the sensor gratings extends in a second, different direction.

7. The method according to claim 5, wherein at least one of the sensor gratings has a pitch that is different from a pitch of at least one other of the sensor gratings.

8. The method according to claim 1, wherein the determining of the at least one property of the second marker feature is performed using a further, different sensor with respect to the image sensor used to determine the image field distortion of the first marker feature.

9. The method according to claim 1, wherein the marker comprises at least one grating.

10. The method according to claim 9, wherein the marker comprises a plurality of gratings, wherein at least one of the gratings extends in a first direction and at least one other of the gratings extends in a second, different direction.

11. The method according to claim 10, wherein there is an offset of phase between at least one of the gratings of the marker and at least one other of the gratings of the marker.

12. The method according to claim 1, wherein the lithographic patterning device comprises a plurality of the markers, and the method comprises determining the image field distortion for each of the plurality of markers.

13. The method according to claim 1, wherein the marker is of a first type, the lithographic patterning device comprises at least one further marker of a second, different type, and the method comprises determining the image field distortion of at least one further marker feature arising from the at least one further marker.

14. The method according to claim 13, wherein the at least one further marker is outside an area of the lithographic patterning device that includes at least one patterning feature for forming the at least one desired lithographic feature on the substrate by projection of radiation via the lithographic patterning device by the lithographic apparatus.

15. The method according to claim 14, wherein the lithographic patterning device further comprises at least one marker of the first type outside the area.

16. The method according to claim 13, further comprising determining an offset between a location of the marker feature or at least one of the marker features arising from the at least one marker of the first type and a location of the at least one further marker feature arising from the at least one marker of the second type.

17. The method according to claim 1, wherein the marker comprises an intra-field overlay marker and/or a diffraction-based overlay marker.

18. The method according to claim 1, further comprising varying, in a direction perpendicular to a plane of the patterning device, a distance between patterning device and the image sensor, obtaining measurements using the image sensor for a plurality of the distances, and determining a focal position and/or a focus correction based on the measurements.

19.-21. (canceled)

22. A lithographic apparatus comprising:
a support structure configured to support a patterning device, the patterning device serving to impart a radiation beam with a pattern in its cross-section;
a substrate table configured to hold a substrate;
a projection system configured to project the patterned radiation beam to provide an image at the substrate table;
a sensor configured to sense at least a region of the image; and
a processing resource configured to at least:
determine an image field distortion of a first marker feature corresponding to a marker of the patterning device, wherein the first marker feature comprises a projected image of the marker obtained by projection of the radiation beam via the patterning device, and the determination of the image field distortion of the projected image of the marker comprises using the sensor to sense radiation of the projected image prior to formation of the at least one desired lithographic feature on the substrate; and
determine at least one property, different from image field distortion, of a second marker feature arising from the same marker, after formation of the at least one desired lithographic feature on the substrate.

23. The lithographic apparatus according to claim 22, wherein the marker is located within an area of the lithographic patterning device that includes at least one patterning feature for forming the at least one desired lithographic feature on the substrate by projection of radiation via the lithographic patterning device by the lithographic apparatus.
